(19) United States
(12) Patent Application Publication
(10) Pub. No.: US 2019/0327864 A1
(43) Pub. Date: Oct. 24, 2019

(54) HEAT SINK FOR A DISPLAY UNIT

(71) Applicant: MAN ZAI INDUSTRIAL CO., LTD., Tainan City (TW)

(72) Inventors: Cheng-Chien Wan, Tainan City (TW); Cheng-Feng Wan, Tainan City (TW); Hao-Hui Lin, Tainan City (TW); Wei-Che Hsiao, Tainan City (TW); Hsiao-Ching Chen, Tainan City (TW); Tung-Hsin Liu, Tainan City (TW)

(73) Assignee: MAN ZAI INDUSTRIAL CO., LTD., Tainan City (TW)

(21) Appl. No.: 16/262,259

(22) Filed: Jan. 30, 2019

(30) Foreign Application Priority Data
Apr. 24, 2018 (TW) 107113851

(51) Int. Cl. H05K 7/20; F28F 3/04; H05K 5/00

(52) U.S. Cl. CPC H05K 7/20963; F28F 3/04; F28F 2250/08; H05K 7/20972; H05K 5/0017; H05K 7/2099

(57) ABSTRACT

A heat sink is applied to a display unit and has a heat conductor, at least one first cooling fan, and at least one second cooling fan. The heat conductor has a heat-conducting member, multiple first cooling fins, and multiple second cooling fins. The heat-conducting member has a base portion, an extending portion formed on the base portion, and multiple channels formed in the heat-conducting member and filled with a working fluid. The first cooling fins are formed on the base portion. The second cooling fins are formed on the extending portion. The at least one first cooling fan is disposed on the base portion. The at least one second cooling fan is disposed on the extending portion. The heat conductor can be sectioned and the working fluid can change phases for heat dissipation, providing a good heat dissipation effect to the heat sink is good.

This application claims the benefit of Taiwan patent application No. 107113851, filed on Apr. 24, 2018, the entire contents of which are incorporated herein by reference.

### BACKGROUND OF THE INVENTION

### 1. Field of the Invention

The present invention relates to a heat sink, and more particularly to a heat sink that is applied to a display unit for heat dissipation.

### 2. Description of Related Art

In a flat-panel display such as a liquid-crystal display, a liquid-crystal panel of a display device provides a backlight source by a backlight module. The backlight source is lighted and generates heat. For keeping a suitable working temperature to the flat-panel display, a conventional heat sink is mounted in a shell of the flat-panel display to assist the flat-panel display with heat dissipation.

The conventional heat sink has a heat-conducting element having multiple cooling fins and at least one cooling fan. The heat-conducting element is connected to a heating source such as the backlight module for increasing a heat dissipation surface area. The at least one cooling fan provides a heat dissipation air flow to the heat-conducting element for heat dissipation.

Although the conventional heat sink uses the combination of the heat-conducting element and the at least one cooling fan for heat dissipation to the flat-panel display, the heat dissipation effect of the conventional heat sink is still insufficient.

To overcome the shortcomings, the present invention provides a heat sink for a display unit to mitigate or obviate the aforementioned problems.

### SUMMARY OF THE INVENTION

The objective of the invention is to provide a heat sink for a display unit that can solve the problem that the heat dissipation effect of the conventional heat sink is insufficient.

The display unit has an outer shell, an inner shell, a display device, an outer chamber, and an inner chamber. The inner shell is disposed in the outer shell. The display device is disposed on the inner shell. The outer chamber is formed between the inner shell and the outer shell. The inner chamber is formed in the inner shell.

The heat sink is disposed in the outer shell of the display unit, extends from the inner chamber to the outer chamber, and has a heat conductor, at least one first cooling fan, and at least one second cooling fan.

The heat conductor is made of a heat-conducting material and has a heat-conducting member, multiple first cooling fins, and multiple second cooling fins. The heat-conducting member has a base portion, an extending portion, and multiple channels. The base portion is disposed in the inner chamber of the display unit and has an end, a front surface, a heat-conducting surface, and a back surface. The heat-conducting surface is formed on the front surface of the base portion. The extending portion is formed on the end of the base portion and is disposed in the outer chamber of the display unit. The channels are closed-form channels, are formed in the heat-conducting member at spaced intervals, extend from the base portion to the extending portion, and are filled with a working fluid. The first cooling fins are formed on and are protruded out of the back surface of the base portion at spaced intervals. The second cooling fins are formed on and are protruded out of the extending portion.

The at least one first cooling fan is disposed on the back surface of the base portion. The at least one second cooling fan is disposed on the extending portion of the heat-conducting member.

The heat sink is applied to the display unit for heat dissipation. Heat generated by a heating source of the display unit is absorbed by the heat conductor. The heat is conducted to the first cooling fins for increasing a heat dissipation surface area. The at least one first cooling fan may generate a heat dissipation air flow for heat dissipation. The working fluid absorbs the heat, changes from a liquid phase to a gas phase, and then flows toward the extending portion of the heat conductor quickly. The heat is conducted to the second cooling fins on the extending portion for increasing the heat dissipation surface area. The at least one second cooling fan generates a heat dissipation air flow for heat dissipation. The working fluid in the gas phase is cooled, changes from the gas phase to the liquid phase, and then flows downwardly via the channels to re-absorb the heat. The heat conductor may be sectioned for heat dissipation. The working fluid changes phases for heat dissipation quickly. Therefore, the heat dissipation effect of the heat sink is good for the display unit.

Other objectives, advantages and novel features of the invention will become more apparent from the following detailed description when taken in conjunction with the accompanying drawings.

### BRIEF DESCRIPTION OF THE DRAWINGS

FIG. 1 is a side view of a first embodiment of a heat sink for a display unit in accordance with the present invention;

FIG. 2 is another side view of the heat sink in FIG. 1;

FIG. 3 is a cross sectional side view of the heat sink along line 3-3 in FIG. 2;

FIG. 4 is a side view of a second embodiment of a heat sink for a display unit in accordance with the present invention; and

FIG. 5 is an operational side view in partial section of the heat sink in FIG. 1, showing the heat sink is disposed on a display device.

### DETAILED DESCRIPTION OF THE PREFERRED EMBODIMENT

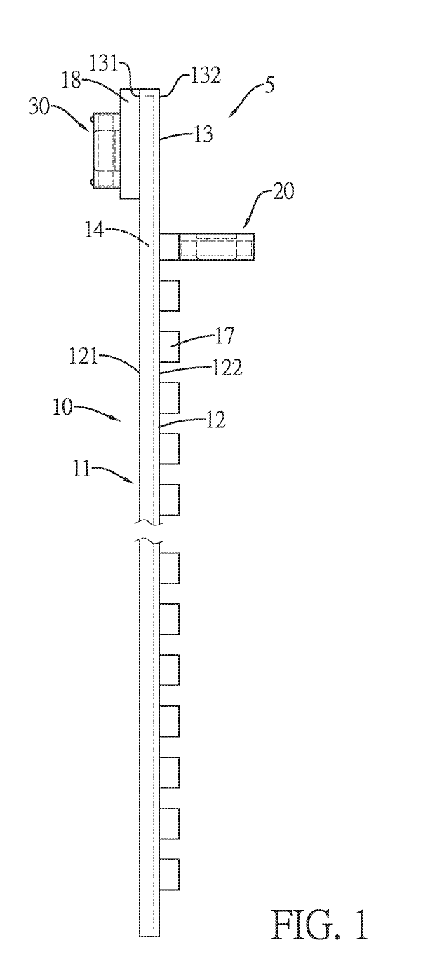

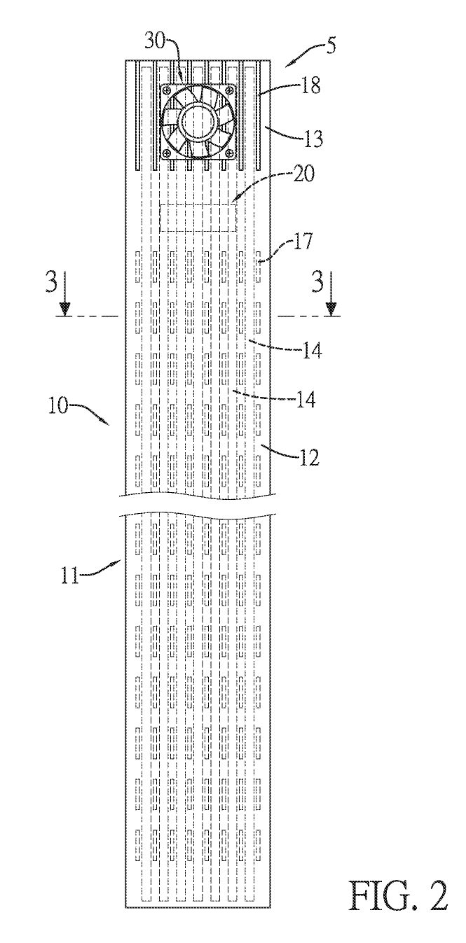

With reference to FIGS. 1 and 2, a first embodiment of a heat sink 5 for a display unit in accordance with the present invention comprises a heat conductor 10, at least one first cooling fan 20, and at least one second cooling fan 30.

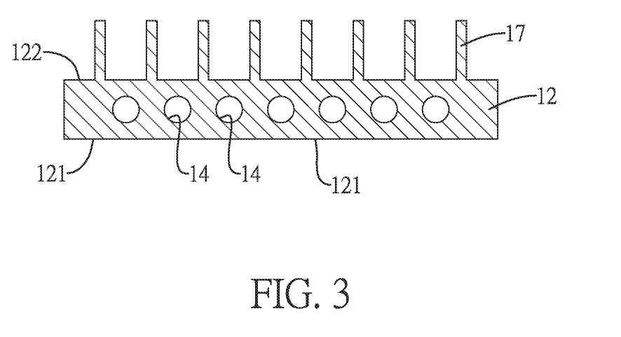

With reference to FIGS. 1 to 3, the heat conductor 10 is made of a heat-conducting material, such as aluminum or aluminum alloy. The heat conductor 10 has a heat-conducting member 11, multiple first cooling fins 17, and multiple second cooling fins 18. The heat-conducting member 11 has a base portion 12, an extending portion 13, and multiple channels 14. The base portion 12 has an end, a front surface, a heat-conducting surface 121, and a back surface 122. The heat-conducting surface 121 is formed on the front surface of the base portion 12. The extending portion 13 is formed on the end of the base portion 12. The channels 14 are closed-form channels, are formed in the heat-conducting member 11 at spaced intervals, extend from the base portion 12 to the extending portion 13, and are filled with a working fluid. The working fluid is phase-changeable, such as refrigerant.

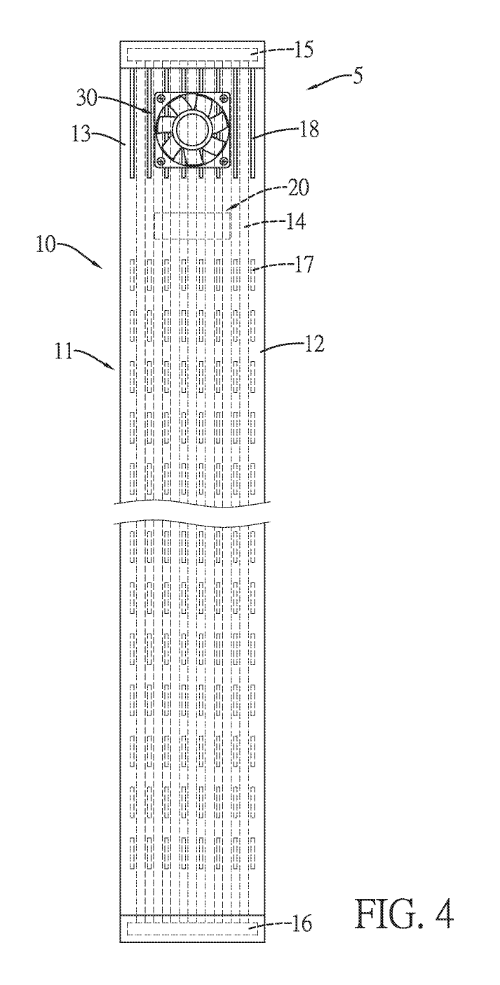

With reference to FIG. 4, in a second embodiment of the heat sink 5, the extending portion 13 of the heat-conducting member 11 has a first connecting chamber 15. The first connecting chamber 15 is formed in the extending portion 13 and is a closed-form chamber. The base portion 12 of the heat-conducting member 11 has a second connecting chamber 16. The second connecting chamber 16 is formed in the base portion 12 and is opposite to the first connecting chamber 15. Two ends of each one of the channels 14 are respectively in communication with the first connecting chamber 15 and the second connecting chamber 16.

In the second embodiment of the heat sink 5, the extending portion 13 is formed on a top end of the base portion 12. The channels 14 in the heat-conducting member 11 extend upwardly from a bottom section of the base portion 12 to the extending portion 13. The first connecting chamber 15 is disposed in a top section of the extending portion 13. The second connecting chamber 16 is disposed in the bottom section of the base portion 12 adjacent to a bottom end of the base portion 12. In addition, the extending portion 13 is formed on a transverse end of the base portion 12 or an inclined end of the base portion 12. The channels 14 may be transverse or inclined. The first connecting chamber 15 and the second connecting chamber 16 are disposed at two transverse ends of the heat conductor 10 or two inclined ends of the heat conductor 10.

With reference to FIGS. 1 and 2, in the heat conductor 10, the first cooling fins 17 are formed on and are protruded out of the back surface 122 of the base portion 12 at spaced intervals. The extending portion 13 has a front surface, a rear surface, a front plate surface 131, and a rear plate surface 132. The front plate surface 131 is formed on the front surface of the extending portion 13. The rear plate surface 132 is formed on the rear surface of the extending portion 13. The second cooling fins 18 are disposed on the front plate surface 131 or the rear plate surface 132 of the extending portion 13. Furthermore, the second cooling fins 18 are disposed on the front plate surface 131 and the rear plate surface 132 of the extending portion 13. In the first embodiment of the heat sink 5, the second cooling fins 18 are disposed on the front plate surface 131 of the extending portion 13.

With reference to FIGS. 1 and 2, the at least one first cooling fan 20 is disposed on the back surface 122 of the base portion 12 and provides a heat dissipation air flow to the back surface 122 having the first cooling fins 17. In the first embodiment of the heat sink 5, the at least one first cooling fan 20 is disposed on a top end of the back surface 122 of the base portion 12 and provides the heat dissipation air flow to the back surface 122 having the first cooling fins 17. The number of the at least one first cooling fan 20 depends on the heat dissipation requirement of the display unit.

With reference to FIGS. 1 and 2, the at least one second cooling fan 30 is disposed on the extending portion 13 of the heat-conducting member 11 and provides a heat dissipation air flow to the extending portion 13 having the second cooling fins 18. In the first embodiment of the heat sink 5, the at least one second cooling fan 30 is disposed in front of the front plate surface 131 of the extending portion 13 and provides the heat dissipation air flow to the extending portion 13 having the second cooling fins 18. The number of the at least one second cooling fan 30 depends on the heat dissipation requirement of the display unit.

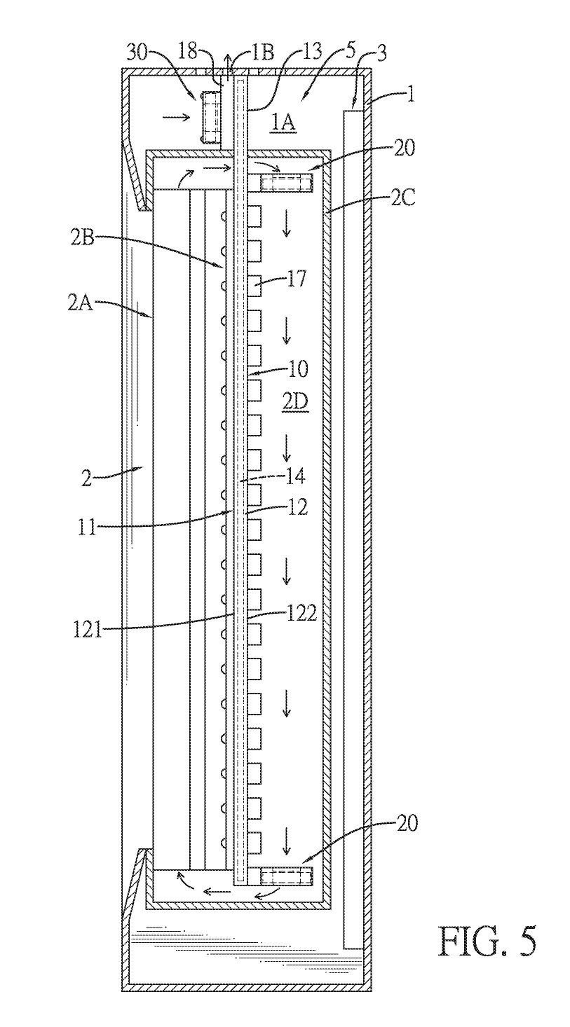

With reference to FIG. 5, the heat sink 5 is applied to the display unit. The display unit has an outer shell 1, a display device 2, and a control circuit board 3. The display device 2 is disposed in the outer shell 1 and has an inner shell 2C, a display panel 2A, and a backlight module 2B. The display panel 2A is exposed out of a front side of the outer shell 1. The backlight module 2B is located behind the display panel 2A. The control circuit board 3 is located behind a rear side of the inner shell 2C. The inner shell 2C has an inner chamber 2D formed in the inner shell 2C. An outer chamber 1A is formed between the inner shell 2C and the outer shell 1. The outer shell 1 has multiple vents 1B formed through a top surface of the outer shell 1. The vents 1B communicate with the outer chamber 1A. Furthermore, the outer shell 1 has multiple through holes (not shown). The through holes are formed through a back of the outer shell 1 for heat dissipation to the control circuit board 3.

The heat sink 5 is disposed in the display unit. The heat conductor 10 is disposed behind the backlight module 2B in the inner shell 2C. The heat conductor 10 extends upwardly from the inner shell 2C to the outer chamber 1A. The heat-conducting surface 121 of the heat-conducting member 11 is connected to the backlight module 2B. The back surface 122 of the base portion 12 having the first cooling fins 17 is located in the inner chamber 2D of the inner shell 2C. The extending portion 13 located on the top end of the base portion 12 is inserted through a top portion of the inner shell 2C and is inserted into the outer chamber 1A formed between the inner shell 2C and the outer shell 1. The extending portion 13 can be best disposed toward a portion of the outer shell 1 having the vents 1B. The at least one first cooling fan 20 is located in the inner chamber 2D of the inner shell 2C. The at least one first cooling fan 20 is disposed above the back surface 122 of the base portion 12 of the heat-conducting member 11. The at least one first cooling fan 20 provides the heat dissipation air flow to the back surface 122 having the first cooling fins 17. The at least one second cooling fan 30 is located in the outer chamber 1A formed between the inner shell 2C and the outer shell 1. The at least one second cooling fan 30 is located in front of the extending portion 13 having the second cooling fins 18. The at least one second cooling fan 30 provides the heat dissipation air flow to the extending portion 13 having the second cooling fins 18.

In use, with reference to FIG. 5, heat generated by the backlight module 2B of the display unit is absorbed by the heat conductor 10 in the heat sink 5. The heat is absorbed by the heat-conducting surface 121 of the base portion 12 connected to the backlight module 2B. Part of the heat is transmitted into the base portion 12 of the heat-conducting member 11. The remaining heat is transmitted to the first cooling fins 17 disposed on the back surface 122 of the base portion 12. The heat dissipation surface area is increased by the first cooling fins 17. The at least one first cooling fan 20 provides the heat dissipation air flow to the back surface 122 having the first cooling fins 17. Therefore, the heat absorbed by the heat-conducting member 11 is dissipated quickly.

With reference to FIG. 5, the working fluid in the channels 14 absorbs the heat transmitted into the heat-conducting member 11 and changes from a liquid phase to a gas phase. The working fluid in the gas phase upwardly and quickly flows from the base portion 12 to the extending portion 13 via the channels 14. The heat transmitted into the heat-conducting member 11 is transmitted to the extending portion 13 and the second cooling fins 18.

With reference to FIG. 4, the first connecting chamber 15 is formed in the top section of the extending portion 13. The channels 14 indirectly communicate with each other via the first connecting chamber 15. In each one of the channels 14, the working fluid in the gas phase can flow into the first connecting chamber 15 for dispersing.

With reference to FIG. 5, the heat dissipation surface area is increased by the second cooling fins 18. The at least one second cooling fan 30 provides the heat dissipation air flow to the extending portion 13 having the second cooling fins 18. Therefore, the heat transmitted to the extending portion 13 can be dissipated quickly. After the working fluid in the gas phase flows to the top sections of the channels 14 and is dissipated, the working fluid can change from the gas phase to the liquid phase. The working fluid in the liquid phase can downwardly flow into the heat-conducting member 11 via the channels 14.

With reference to FIG. 4, the second connecting chamber 16 is formed in a bottom end of the heat-conducting member 11. The channels 14 indirectly communicate with each other via the second connecting chamber 16. In each one of the channels 14, the working fluid in the liquid phase can flow into the second connecting chamber 15 for dispersing.

With reference to FIG. 5, the heat can be absorbed and dissipated by the working fluid flowing cyclically. Furthermore, the heat dissipation air flow generated by the at least one second cooling fan 30 can be dissipated out of the outer shell 1 via the vents 1B.

Accordingly, the heat sink 5 is applied to the display unit for heat dissipation. Heat generated by a heating source of the display unit is absorbed by the heat conductor 10. The heat is conducted to the first cooling fins 17. The heat dissipation surface area is increased by the first cooling fins 17. The at least one first cooling fan 20 generates the heat dissipation air flow for heat dissipation. The working fluid in the channels 14 absorbs the heat, changes from the liquid phase to the gas phase, and then flows toward the extending portion 13 of the heat conductor 10 quickly. The heat dissipation surface area is increased by the second cooling fins 18 on the extending portion 13. The at least one second cooling fan 30 generates the heat dissipation air flow for heat dissipation. The working fluid in the gas phase is cooled, changes from the gas phase to the liquid phase, and then reflows via the channels to re-absorb the heat. The heat conductor can be sectioned for heat dissipation and the working fluid can change phases for heat dissipation quickly, thereby providing the good heat dissipation effect of the heat sink 5 for the display unit.

What is claimed is:

1. A heat sink for a display unit, the display unit having an outer shell, an inner shell, a display device, an outer chamber, and an inner chamber, the inner shell disposed in the outer shell, the display device disposed on the inner shell, the outer chamber formed between the inner shell and the outer shell, and the inner chamber formed in the inner shell, the heat sink disposed in the outer shell of the display unit, extending from the inner chamber to the outer chamber, and comprising:
a heat conductor made of a heat-conducting material and having
a heat-conducting member having
a base portion disposed in the inner chamber of the display unit and having an end, a front surface, a heat-conducting surface, and a back surface, the heat-conducting surface formed on the front surface of the base portion;
an extending portion formed on the end of the base portion and disposed in the outer chamber of the display unit; and
multiple channels being closed-form channels, formed in the heat-conducting member at spaced intervals, extending from the base portion to the extending portion, and filled with a working fluid;
multiple first cooling fins formed on and protruded out of the back surface of the base portion at spaced intervals; and
multiple second cooling fins formed on and protruded out of the extending portion;
at least one first cooling fan disposed on the back surface of the base portion; and
at least one second cooling fan disposed on the extending portion of the heat-conducting member.

2. The heat sink as claimed in claim 1, wherein the extending portion of the heat-conducting member has a first connecting chamber, the first connecting chamber is formed in the extending portion and is a closed-form chamber, the base portion of the heat-conducting member has a second connecting chamber, the second connecting chamber is formed in the base portion and is opposite to the first connecting chamber, and two ends of each one of the channels are respectively in communication with the first connecting chamber and the second connecting chamber.

3. The heat sink as claimed in claim 1, wherein the extending portion has a front surface, a rear surface, a front plate surface, and a rear plate surface, the front plate surface is formed on the front surface of the extending portion, the rear plate surface is formed on the rear surface of the extending portion, and the second cooling fins are disposed on the front plate surface or the rear plate surface of the extending portion.

4. The heat sink as claimed in claim 2, wherein the extending portion has a front surface, a rear surface, a front plate surface, and a rear plate surface, the front plate surface is formed on the front surface of the extending portion, the rear plate surface is formed on the rear surface of the extending portion, and the second cooling fins are disposed on the front plate surface or the rear plate surface of the extending portion.

5. The heat sink as claimed in claim 1, wherein the extending portion has a front surface, a rear surface, a front plate surface, and a rear plate surface, the front plate surface is formed on the front surface of the extending portion, the rear plate surface is formed on the rear surface of the extending portion, and the second cooling fins are disposed on the front plate surface and the rear plate surface of the extending portion.

6. The heat sink as claimed in claim 2, wherein the extending portion has a front surface, a rear surface, a front plate surface, and a rear plate surface, the front plate surface is formed on the front surface of the extending portion, the rear plate surface is formed on the rear surface of the extending portion, and the second cooling fins are disposed on the front plate surface and the rear plate surface of the extending portion.
